(19) United States
(12) Patent Application Publication
(10) Pub. No.: US 2025/0311190 A1
(43) Pub. Date: Oct. 2, 2025

(54) SEMICONDUCTOR DEVICE, MANUFACTURING METHOD THEREFOR AND DYNAMIC RANDOM ACCESS MEMORY

(71) Applicant: CXMT Corporation, Hefei City (CN)

(72) Inventors: Yanqin WANG, Hefei City (CN); Meng HUANG, Hefei City (CN); Sijia LI, Hefei City (CN); Hao SHI, Hefei City (CN)

(73) Assignee: CXMT Corporation, Hefei City (CN)

(21) Appl. No.: 18/968,150

(22) Filed: Dec. 4, 2024

Related U.S. Application Data
(63) Continuation of application No. PCT/CN2024/124339, filed on Oct. 12, 2024.

(30) Foreign Application Priority Data
Mar. 29, 2024 (CN) 202410374584.2

(51) Int. Cl. H10B 12/00; G11C 11/4091; H10D 1/68

(52) U.S. Cl. CPC H10B 12/31; G11C 11/4091; H10B 12/05; H10B 12/488; H10D 1/716

(57) ABSTRACT

The present disclosure provides a semiconductor device and a dynamic random access memory. The semiconductor device includes a substrate and a first structural unit disposed on the substrate. The first structural unit includes a plurality of transistors, and the plurality of transistors are stacked along a first direction. The plurality of transistors include at least a first transistor and a second transistor, where a width of a channel region of the first transistor far away from the substrate along the first direction is less than a width of a channel region of the second transistor close to the substrate.

### CROSS-REFERENCE TO RELATED APPLICATIONS

This is a continuation application of International Patent Application No. PCT/CN2024/124339 filed on Oct. 12, 2024, which claims priority to Chinese Patent Application No. 202410374584.2 filed on Mar. 29, 2024. The disclosures of the above-referenced applications are hereby incorporated by reference in in their entirety.

### BACKGROUND

With the development of dynamic random access memory (DRAM) technologies, the size of the memory cell becomes increasingly small, and a conventional structure almost approaches its size limit. To obtain a DRAM device with higher capacity, engineers have developed a three-dimensional dynamic memory structure.

However, as the quantity of layers of the three-dimensional dynamic memory structure increases, many technical problems that the conventional structure has not yet met appear in the manufacturing process and need to be urgently resolved.

### SUMMARY

Based on this, the present disclosure provides a semiconductor structure and a method for manufacturing the same, which can reduce the device volume and reduce the difficulty of the manufacturing process.

The present disclosure relates to the field of integrated circuit technologies, and in particular, to a semiconductor structure, and more specifically, to a three-dimensional dynamic memory structure.

According to an embodiment of the present disclosure, a semiconductor device is provided. The semiconductor device includes a substrate and a first structural unit disposed on the substrate, where the first structural unit includes a plurality of transistors, and the plurality of transistors are stacked along a first direction;
each of the plurality of transistors includes: a gate structure, an active layer, a first electrode, and a second electrode, the first electrode and the second electrode being respectively disposed on two sides of the gate structure along a second direction, the active layer being connected to the first electrode and the second electrode, the active layer including a channel region, and the channel region being located between the first electrode and the second electrode;
the gate structures of the plurality of transistors are connected along the first direction;
the first direction intersects with a plane on which the substrate is located, and the second direction intersects with the first direction;
the plurality of transistors include at least a first transistor and a second transistor, where a width of a channel region of the first transistor far away from the substrate along the first direction is less than a width of a channel region of the second transistor close to the substrate.

According to another embodiment of the present disclosure, in the semiconductor device, for widths of channel regions of the plurality of transistors, the farther away from the substrate along the first direction, the smaller the width of the channel region.

According to another embodiment of the present disclosure, the semiconductor device includes a plurality of first structural units stacked along the first direction, where the gate structures of the plurality of first structural units are connected along the first direction.

According to another embodiment of the present disclosure, the semiconductor device includes a plurality of first structural units disposed along a third direction, where the third direction intersects with the second direction;
the second electrodes of the transistors disposed at a same layer of the plurality of first structural units are connected to a same bit line, and the bit line is disposed along a third direction.

According to another embodiment of the present disclosure, in the semiconductor device, the first structural unit further includes:
a plurality of capacitor structures, where the plurality of capacitor structures are stacked along the first direction; each of the plurality of capacitor structures includes a first capacitor electrode, a second capacitor electrode, and a capacitor dielectric layer disposed between the first capacitor electrode and the second capacitor electrode; the plurality of capacitor structures and the plurality of transistors are correspondingly disposed along the second direction, and the first capacitor electrode of the capacitor structure is connected to the first electrode of a corresponding transistor; the second capacitor electrodes of the plurality of capacitor structures are connected along the first direction.

According to another embodiment of the present disclosure, in the semiconductor device, the first capacitor electrode is disposed as a ring around the second capacitor electrode, and a width of the second capacitor electrode corresponding to the first transistor in the first direction is less than a width of the second capacitor electrode corresponding to the second transistor in the first direction.

According to another embodiment of the present disclosure, in the semiconductor device, a material of the active layer is an oxide semiconductor material.

According to another embodiment of the present disclosure, in the semiconductor device, the oxide semiconductor material is indium gallium zinc metal oxide doped with tin.

According to another embodiment of the present disclosure, in the semiconductor device, the second electrode and/or the first electrode are selected from one or more of: metallic ruthenium, metallic molybdenum, ruthenium oxide, or molybdenum oxide.

According to another embodiment of the present disclosure, in the semiconductor device, the first capacitor electrode is selected from one or more of: metallic ruthenium, metallic molybdenum, ruthenium oxide, or molybdenum oxide.

According to another embodiment of the present disclosure, in the semiconductor device, the first capacitor electrode and the first electrode are integrally formed.

According to another embodiment of the present disclosure, in the semiconductor device, the first capacitor electrode and the first electrode include metallic ruthenium.

According to another embodiment of the present disclosure, in the semiconductor device, the capacitor dielectric layer includes strontium titanium oxide.

According to an embodiment of the present disclosure, a dynamic random access memory is provided. The dynamic random access memory includes: the semiconductor device according to the foregoing description, a sub-word line driver connected to the gate structures, and a sense amplifier connected to the second electrodes.

According to another embodiment of the present disclosure, in the dynamic random access memory, the sub-word line driver and/or the sense amplifier are disposed on the substrate.

According to another embodiment of the present disclosure, in the dynamic random access memory, the sub-word line driver and/or the sense amplifier are disposed on a control substrate, the control substrate being bonded to the substrate.

The semiconductor structure and the dynamic random access memory provided by the present disclosure have at least the following beneficial effects:
The semiconductor structure and the dynamic random access memory provided by the present disclosure feature better uniformity among transistors at different layers, higher storage capacity, more excellent semiconductor performance, and more excellent storage performance.

### BRIEF DESCRIPTION OF THE DRAWINGS

To more clearly illustrate technical solutions in embodiments of the present disclosure or the conventional technology, a brief introduction to the drawings required for the description of the embodiments or conventional technology is given hereinafter. It is evident that the drawings described hereinafter are merely some embodiments of the present disclosure. For those of ordinary skill in the art, other drawings may also be obtained based on these drawings without creative effort.

FIG. 1 is a schematic view of a semiconductor structure provided according to some embodiments of the present disclosure;

FIG. 2 is a schematic view of a semiconductor structure provided according to some other embodiments of the present disclosure;

FIG. 3 is a schematic view of a semiconductor structure provided according to some other embodiments of the present disclosure;

FIG. 4 is a schematic view of a semiconductor structure provided according to some other embodiments of the present disclosure;

FIG. 5 is a schematic view of a dynamic random access memory provided according to some embodiments of the present disclosure;

FIG. 6 is a schematic view of a dynamic random access memory provided according to some other embodiments of the present disclosure;

FIG. 7 is a schematic view of a dynamic random access memory provided according to some other embodiments of the present disclosure.

### DETAILED DESCRIPTION

To facilitate understanding of the present disclosure, a more comprehensive description of the present disclosure will be provided hereinafter with reference to the relevant drawings. The drawings illustrate preferred embodiments of the present disclosure. However, the present disclosure can be implemented in many different forms and is not limited to the embodiments described herein. Rather, these embodiments are provided to make the disclosed content more thorough and comprehensive.

Unless otherwise defined, all technical and scientific terms used herein have the same meaning as commonly understood by those skilled in the art to which the present disclosure belongs. The terms used in the specification of the present disclosure are for the purpose of describing particular embodiments only and are not intended to limit the present disclosure.

It should be appreciated that when an element or a layer is referred to as being “on”, “adjacent to”, “connected to”, or “coupled to” another element or layer, it may be directly on, adjacent to, connected to, or coupled to the another element or layer, or an intervening element or layer may be present. On the contrary, when an element is referred to as being “directly on”, “directly adjacent to”, “directly connected to”, or “directly coupled to” another element or layer, no intervening element or layer is present. It should be appreciated that, although the terms first, second, third, and the like may be used to describe various elements, components, regions, layers, doping types, and/or portions, the elements, components, regions, layers, doping types, and/or portions should not be limited by the terms. These terms are only used to distinguish one element, component, region, layer, doping type, or portion from another element, component, region, layer, doping type, or portion. Thus, a first element, component, region, layer, doping type, or portion discussed below can be termed a second element, component, region, layer, or portion without departing from the teachings of the present disclosure. For example, the first doping type may be made the second doping type, and similarly, the second doping type may be made the first doping type. The first doping type and the second doping type are different doping types. For example, the first doping type may be P-type and the second doping type may be N-type, or the first doping type may be N-type and the second doping type may be P-type.

Spatial relationship terms such as “under”, “below”, “underneath”, “beneath”, “on”, and “above” may be used herein to describe the relationship between an element or a feature shown in the figures and other elements or features. It should be appreciated that the spatial relationship terms include different orientations of the device in use or operation in addition to the orientation illustrated in the figures. For example, if the device in the figures is turned over, elements or features described as being “below”, “beneath”, or “under” other elements or features would then be oriented “above” the other elements or features. Therefore, the exemplary terms “below” and “under” may include both up and down orientations. In addition, the device may also include other orientations (such as rotated 90 degrees or at other orientations), and the spatial descriptive terms used herein should be interpreted accordingly.

As used herein, the singular forms “a”, “an”, and “the” may include the plural forms as well, unless the context clearly indicates otherwise. It should also be appreciated that the terms “comprise” and/or “include” when used in the specification, specify the presence of stated features, integers, steps, operations, elements, and/or components, but do not preclude the presence or addition of one or more other features, integers, steps, operations, elements, components, and/or groups. Additionally, as used herein, the term “and/or” includes any and all combinations of the associated listed items.

The embodiments of the present disclosure are described herein with reference to the schematic cross-sectional views of the ideal embodiments (and intermediate structures) of the present disclosure, such that variations in the shapes shown resulting from, e.g., manufacturing techniques and/or tolerances, are to be expected. Therefore, the embodiments of the present disclosure should not be limited to the specific shapes of regions shown herein but should include shape deviations resulting from, e.g., manufacturing techniques. For example, an injection region shown as a rectangle typically has rounded or curved features and/or injection concentration gradients on edges of the injection region, rather than a binary change from the injection region to a non-injection region. Similarly, an implantation region formed through injection can result in some injection in a region between the implantation region and a surface that has been passed through when the injection is performed. Therefore, the regions shown in the figures are essentially illustrative, and their shapes do not represent actual shapes of the regions of the device, nor do they limit the scope of the present disclosure.

In a related embodiment, a three-dimensional stacked transistor structure, as a new-type semiconductor structure, is often used in a high-density integrated circuit structure due to its excellent capacity scalability. For the three-dimensional stacked transistor structure, a source and a drain are disposed at a same layer, a hole penetrating through the stack structure is provided between the source and the drain, an active layer and a gate structure are disposed in the hole, and the active layer corresponding to the source and the drain is a channel region. During research and development, the inventor finds that if thicknesses of layers of the stack structure are uniform, a transistor structure at an upper layer and a transistor structure at a lower layer have different performance and relatively poor uniformity, and the difference between the performance of a transistor at an uppermost layer and the performance of a transistor at a lowermost layer becomes more obvious as the quantity of deposited layers increases.

The inventor obtains a measurement result after simulation by using simulation software and then finds the following problems by analyzing the simulation result:

For stacked transistors, as the quantity of layers increases, the aperture of an upper layer is greater than that of a lower layer due to the impact of the diffusion speed of an etching solution during manufacturing of the hole between the source and the drain, thereby resulting in a tapered cross section in a direction perpendicular to a substrate. Because the channel length varies due to the impact of the tapered cross section, the transistor performance is shown as that the saturation currents of transistors gradually decrease from the upper layer to the lower layer under a same gate turn-on voltage.

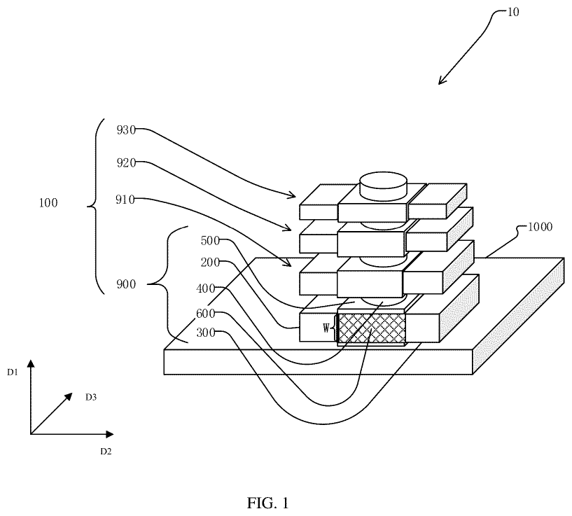

In view of this, the present disclosure provides a semiconductor device in some embodiments. As shown in FIG. 1, a semiconductor device 10 includes: a substrate 1000 and a first structural unit 100 disposed on the substrate 1000. The first structural unit 100 includes transistors (900, 910, 920, 930). A plurality of transistors (900, 910, 920, 930) are stacked along a first direction D1. The transistor 900 is used as an example and includes: a gate structure 400, an active layer 500, a first electrode 200, and a second electrode 300. The first electrode 200 and the second electrode 300 are respectively disposed on two sides of the gate structure 400 along a second direction D2. The active layer 500 is connected to the first electrode 200 and the second electrode 300; the active layer 500 includes a channel region 600, and the channel region 600 is located between the first electrode 200 and the second electrode 300. Gate structures of the plurality of transistors (900, 910, 920, 930) are connected along the first direction D1. The first direction D1 intersects with a plane on which the substrate 1000 is located, and the second direction D2 intersects with the first direction D1. The plurality of transistors (900, 910, 920, 930) include at least a first transistor and a second transistor, where the width W of the channel region of the transistor, for example, the first transistor 930, far away from the substrate along the first direction D1 is less than the width W of the channel region of the second transistor 900 close to the substrate. A third direction D3 intersects with the second direction D2.

In some other embodiments, optionally, for widths of channel regions of the plurality of transistors, the farther away from the substrate along the first direction, the smaller the width of the channel region.

A specific manufacturing manner is as follows: First, a stack structure is manufactured on the substrate. The stack structure is made by depositing two different material layers alternately. The two material layers have a certain etching selectivity, which is used for selective etching in a subsequent manufacturing process to form a required structure. One material layer is a supporting layer and the other material layer is a sacrificial layer. Optionally, silicon layers and silicon germanium layers are deposited alternately to form a stack structure. Optionally, silicon nitride and silicon oxide are deposited alternately to form a stack structure. One or more of factors such as a deposition rate, a deposition time, a reaction temperature, or a reaction gas flow rate of each layer are adjusted to adjust the thickness of a deposited layer. The thickness of a supporting layer formed close to the substrate through deposition is greater than the thickness of a supporting layer far away from the substrate.

In some other embodiments, the thickness of the supporting layer decreases as the distance from the substrate increases.

In some other embodiments, as a whole, the thickness of the supporting layer decreases as the distance from the substrate increases, but thicknesses of adjacent supporting layers may be equal. For example, thicknesses of every few supporting layers are equal, and thicknesses of several supporting layers subsequently deposited are also equal but less than the thicknesses of several supporting layers previously deposited.

In some other embodiments, sacrificial layers have the same thickness.

In some other embodiments, similar to the supporting layer, the thickness of the sacrificial layer decreases as the distance from the substrate increases.

In some other embodiments, the sacrificial layer has an opposite trend to the supporting layer, that is, the thickness of the sacrificial layer gradually increases as the distance from the substrate increases.

In some other embodiments, the deposition method may be selected from one or more of a high-temperature furnace, chemical vapor deposition, physical vapor deposition, or atomic layer deposition.

Two holes or grooves are formed on the stack structure obtained above through etching, and the supporting layers are laterally etched through the holes or grooves to form lateral grooves. The first electrode and the second electrode are respectively formed in the lateral grooves of the two holes or grooves. Because the first electrode and the second electrode are formed in the lateral grooves and the width of the lateral grooves in the first direction is related to the thickness of the supporting layer, the thickness of the first electrode and the thickness of the second electrode are related to the thickness of the corresponding supporting layer.

In some other embodiments, the etching process for manufacturing holes or grooves is selected from dry etching or wet etching.

In some other embodiments, the etching process for lateral etching is selected from dry etching or wet etching.

In some other embodiments, the manufacturing method for the first electrode and the second electrode includes: first depositing a continuous metal film layer covering the surface of the stack structure, the surface of the hole or the groove, the substrate exposed by the hole or the groove, and the inside of the lateral grooves; and retaining the metal film layer in the lateral grooves by using an anisotropic etching method to form the first electrodes and the second electrodes, and removing the metal film layer in other parts.

In some other embodiments, the manufacturing process for depositing the metal film layer is selected from one or more of a high-temperature furnace, chemical vapor deposition, physical vapor deposition, or atomic layer deposition.

On the stack structure, a gate hole is formed by etching between the first electrode and the second electrode to ensure that the first electrode and the second electrode are exposed, and the active layer is formed between the first electrode and the second electrode in the gate hole. The gate structure is formed in the gate hole in which the active layer is formed, and the gate structure includes an outer gate insulating layer and a gate electrode wrapped in the gate insulating layer. A portion of the active layer, which is corresponding to the first electrode and the second electrode, is the channel region, and because the thickness of the first electrode and the thickness of the second electrode are related to the thickness of the supporting layer, the thickness of the channel region is also related to the thickness of the supporting layer.

In some other embodiments, the gate hole is formed before the first electrode and the second electrode are formed, or the gate hole is formed in the same step as the hole or groove formed when the first electrode and the second electrode are manufactured. After being manufactured, the gate hole is filled with a filling material. After the first electrode and the second electrode are formed, the filling material is removed to proceed to a subsequent step.

In some other embodiments, the manufacturing of the active layer includes: forming a continuous semiconductor material layer on a sidewall of the gate hole and filling the gate hole, where optionally, the gate hole is filled once the gate structure is manufactured or the gate hole is filled with a filling material; and removing the sacrificial layer in the stack structure to expose the semiconductor material layer, and etching away the semiconductor material layer at a position where the sacrificial layer is the least to form the active layer.

In some other embodiments, the gate structure is manufactured by first depositing the gate insulating layer, optionally one or more of an oxide, a nitride, or an oxynitride, and then manufacturing a gate, optionally one or more of a metal, an alloy, a conductive compound, or polysilicon, in the gate hole in which the gate insulating layer is deposited.

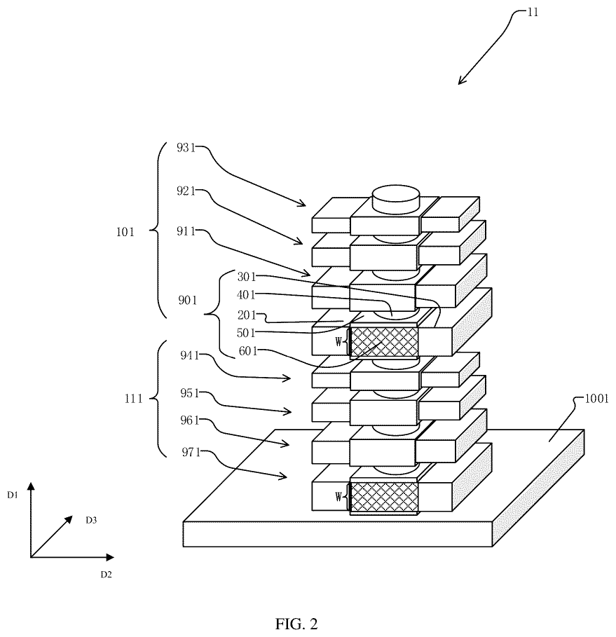

The present disclosure provides a semiconductor device in some other embodiments. As shown in FIG. 2, a semiconductor device 11 includes: a substrate 1001 and first structural units (101, 111) disposed on the substrate 1001. The first structural unit 101 includes transistors (901, 911, 921, 931). A plurality of transistors (901, 911, 921, 931) are stacked along a first direction D1. The transistor 901 is used as an example and includes: a gate structure 401, an active layer 501, a first electrode 201, and a second electrode 301. The first electrode 201 and the second electrode 301 are respectively disposed on two sides of the gate structure 401 along a second direction D2. The active layer 501 is connected to the first electrode 201 and the second electrode 301; the active layer 501 includes a channel region 601, and the channel region 601 is located between the first electrode 201 and the second electrode 301. Gate structures of the plurality of transistors (901, 911, 921, 931) are connected along the first direction D1. The first direction D1 intersects with a plane on which the substrate 1001 is located, and the second direction D2 intersects with the first direction D1. The plurality of transistors (901, 911, 921, 931) include at least a first transistor and a second transistor, where the width W of the channel region of the transistor, for example, the first transistor 931, far away from the substrate along the first direction D1 is less than the width W of the channel region of the second transistor 901 close to the substrate. A plurality of first structural units (101, 111) are stacked along the first direction, and gate structures 401 of the plurality of first structural units are connected along the first direction D1. A third direction D3 intersects with the second direction D2.

A specific manufacturing manner is as follows: First, a stack structure is manufactured on the substrate. The stack structure is made by depositing two different material layers alternately. The two material layers have a certain etching selectivity, which is used for selective etching in a subsequent manufacturing process to form a required structure. One material layer is a supporting layer and the other material layer is a sacrificial layer. Optionally, silicon layers and silicon germanium layers are deposited alternately to form a stack structure. Optionally, silicon nitride and silicon oxide are deposited alternately to form a stack structure. One or more of factors such as a deposition rate, a deposition time, a reaction temperature, or a reaction gas flow rate of each layer are adjusted to adjust the thickness of a deposited layer. The thickness of a supporting layer formed close to the substrate through deposition is greater than the thickness of a supporting layer far away from the substrate.

In some other embodiments, the thickness of the supporting layer decreases as the distance from the substrate increases.

In some other embodiments, as a whole, the thickness of the supporting layer decreases as the distance from the substrate increases, but thicknesses of adjacent supporting layers may be equal. For example, thicknesses of every few supporting layers are equal, and thicknesses of several supporting layers subsequently deposited are also equal but less than the thicknesses of several supporting layers previously deposited.

In some other embodiments, sacrificial layers have the same thickness.

In some other embodiments, similar to the supporting layer, the thickness of the sacrificial layer decreases as the distance from the substrate increases.

In some other embodiments, the sacrificial layer has an opposite trend to the supporting layer, that is, the thickness of the sacrificial layer gradually increases as the distance from the substrate increases.

In some other embodiments, the deposition method may be selected from one or more of a high-temperature furnace, chemical vapor deposition, physical vapor deposition, or atomic layer deposition.

Two holes or grooves are formed on the stack structure obtained above through etching, and the supporting layers are laterally etched through the holes or grooves to form lateral grooves. The first electrode and the second electrode are respectively formed in the lateral grooves of the two holes or grooves. Because the first electrode and the second electrode are formed in the lateral grooves and the width of the lateral grooves in the first direction is related to the thickness of the supporting layer, the thickness of the first electrode and the thickness of the second electrode are related to the thickness of the corresponding supporting layer.

In some other embodiments, the etching process for manufacturing holes or grooves is selected from dry etching or wet etching.

In some other embodiments, the etching process for lateral etching is selected from dry etching or wet etching.

In some other embodiments, the manufacturing method for the first electrode and the second electrode includes: first depositing a continuous metal film layer covering the surface of the stack structure, the surface of the hole or the groove, the substrate exposed by the hole or the groove, and the inside of the lateral grooves; and retaining the metal film layer in the lateral grooves by using an anisotropic etching method to form the first electrodes and the second electrodes, and removing the metal film layer in other parts.

In some other embodiments, the manufacturing process for depositing the metal film layer is selected from one or more of a high-temperature furnace, chemical vapor deposition, physical vapor deposition, or atomic layer deposition.

On the stack structure, a gate hole is formed by etching between the first electrode and the second electrode to ensure that the first electrode and the second electrode are exposed, and the active layer is formed between the first electrode and the second electrode in the gate hole. The gate structure is formed in the gate hole in which the active layer is formed, and the gate structure includes an outer gate insulating layer and a gate electrode wrapped in the gate insulating layer. A portion of the active layer, which is corresponding to the first electrode and the second electrode, is the channel region, and because the thickness of the first electrode and the thickness of the second electrode are related to the thickness of the supporting layer, the thickness of the channel region is also related to the thickness of the supporting layer.

In some other embodiments, the gate hole is formed before the first electrode and the second electrode are formed, or the gate hole is formed in the same step as the hole or groove formed when the first electrode and the second electrode are manufactured. After being manufactured, the gate hole is filled with a filling material. After the first electrode and the second electrode are formed, the filling material is removed to proceed to a subsequent step.

In some other embodiments, the manufacturing of the active layer includes: forming a continuous semiconductor material layer on a sidewall of the gate hole and filling the gate hole, where optionally, the gate hole is filled once the gate structure is manufactured or the gate hole is filled with a filling material; and removing the sacrificial layer in the stack structure to expose the semiconductor material layer, and etching away the semiconductor material layer at a position where the sacrificial layer is the least to form the active layer.

In some other embodiments, the gate structure is manufactured by first depositing the gate insulating layer, optionally one or more of an oxide, a nitride, or an oxynitride, and then manufacturing a gate, optionally one or more of a metal, an alloy, a conductive compound, or polysilicon, in the gate hole in which the gate insulating layer is deposited.

In some other embodiments, a plurality of first structural units are disposed from bottom to top, and all the first structural units are manufactured by using the foregoing manufacturing process and have a similar manufacturing procedure; gate structures of adjacent first structural units in a vertical direction are aligned and linked.

In some other embodiments, a plurality of first structural units are disposed from bottom to top, each first structural unit is manufactured by using the foregoing manufacturing process, a part of the manufacturing process is first implemented on each first structural unit, and finally processes that may be integrated are performed in the same step for manufacturing. Optionally, after holes or grooves are first manufactured in the stack structure and then filled with a filling material, another stack structure is manufactured on the upper layer of the stack structure and then holes or grooves are manufactured at corresponding positions, and so on. After all the stack structures with the holes or grooves are manufactured, for different first structural units, at least one of the first electrode, the second electrode, the active layer, or the gate structure is manufactured at the same time.

In some other embodiments, between transistors in two of the plurality of first structural units disposed from bottom to top, there is no such relationship that the width of the channel region of the transistor far away from the substrate is greater than the width of the channel region of the transistor close to the substrate.

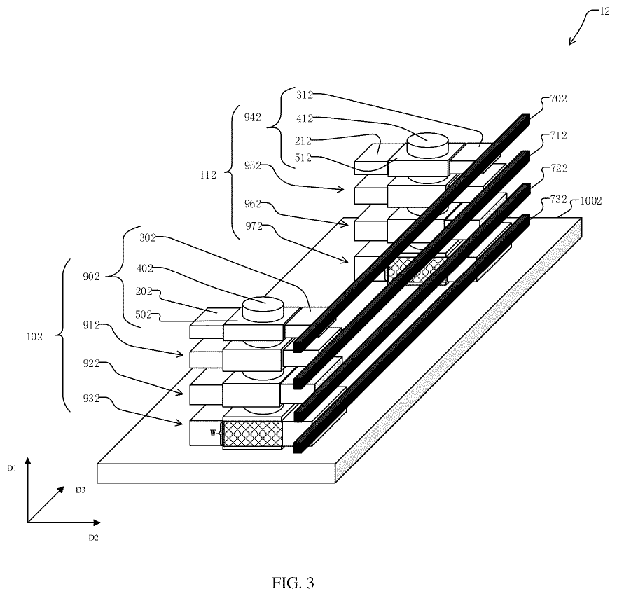

In some other embodiments, as shown in FIG. 3, a semiconductor device 12 includes: a substrate 1002 and first structural units (102,112) disposed on the substrate 1002. The first structural units (102, 112) include transistors (902, 912, 922, 932, 942, 952, 962, 972). A plurality of transistors (902, 912, 922, 932, 942, 952, 962, 972) are stacked along a first direction D1. The transistors (902, 942) are used as an example and each include: a gate structure (402, 412), an active layer (502, 512), a first electrode (202, 212), and a second electrode (302, 312). The first electrode and the second electrode are respectively disposed on two sides of the gate structure along a second direction D2. The active layer is connected to the first electrode and the second electrode; the active layer includes a channel region, and the channel region is located between the first electrode and the second electrode. Gate structures of a plurality of transistors (902, 912, 922, 932) are connected along the first direction D1. The first direction D1 intersects with a plane on which the substrate 1002 is located, and the second direction D2 intersects with the first direction D1. The plurality of transistors (902, 912, 922, 932) include at least a first transistor and a second transistor, where the width W of the channel region of the transistor, for example, the first transistor 902, far away from the substrate along the first direction D1 is less than the width W of the channel region of the second transistor 932 close to the substrate. Similarly, in a plurality of transistors (942, 952, 962, 972), the width of the channel region of the transistor 942 is less than the width of the channel region of the transistor 972. For a plurality of first structural units (102, 112) disposed on the substrate 1002 along a third direction D3, the third direction D3 intersects with the second direction D2. Second electrodes of transistors disposed at the same layer of the plurality of first structural units are connected to the same bit line (702, 712, 722, 732), and the bit line is disposed along the third direction.

A specific manufacturing manner is as follows: First, a stack structure is manufactured on the substrate. The stack structure is made by depositing two different material layers alternately. The two material layers have a certain etching selectivity, which is used for selective etching in a subsequent manufacturing process to form a required structure. One material layer is a supporting layer and the other material layer is a sacrificial layer. Optionally, silicon layers and silicon germanium layers are deposited alternately to form a stack structure. Optionally, silicon nitride and silicon oxide are deposited alternately to form a stack structure. One or more of factors such as a deposition rate, a deposition time, a reaction temperature, or a reaction gas flow rate of each layer are adjusted to adjust the thickness of a deposited layer. The thickness of a supporting layer formed close to the substrate through deposition is greater than the thickness of a supporting layer far away from the substrate.

In some other embodiments, the thickness of the supporting layer decreases as the distance from the substrate increases.

In some other embodiments, as a whole, the thickness of the supporting layer decreases as the distance from the substrate increases, but thicknesses of adjacent supporting layers may be equal. For example, thicknesses of every few supporting layers are equal, and thicknesses of several supporting layers subsequently deposited are also equal but less than the thicknesses of several supporting layers previously deposited.

In some other embodiments, sacrificial layers have the same thickness.

In some other embodiments, similar to the supporting layer, the thickness of the sacrificial layer decreases as the distance from the substrate increases.

In some other embodiments, the sacrificial layer has an opposite trend to the supporting layer, that is, the thickness of the sacrificial layer gradually increases as the distance from the substrate increases.

In some other embodiments, the deposition method may be selected from one or more of a high-temperature furnace, chemical vapor deposition, physical vapor deposition, or atomic layer deposition.

Two holes or grooves are formed on the stack structure obtained above through etching, and the supporting layers are laterally etched through the holes or grooves to form lateral grooves. The first electrode and the second electrode are respectively formed in the lateral grooves of the two holes or grooves. Because the first electrode and the second electrode are formed in the lateral grooves and the width of the lateral grooves in the first direction is related to the thickness of the supporting layer, the thickness of the first electrode and the thickness of the second electrode are related to the thickness of the corresponding supporting layer.

In some other embodiments, the etching process for manufacturing holes or grooves is selected from dry etching or wet etching.

In some other embodiments, the etching process for lateral etching is selected from dry etching or wet etching.

In some other embodiments, the manufacturing method for the first electrode and the second electrode includes: first depositing a continuous metal film layer covering the surface of the stack structure, the surface of the hole or the groove, the substrate exposed by the hole or the groove, and the inside of the lateral grooves; and retaining the metal film layer in the lateral grooves by using an anisotropic etching method to form the first electrodes and the second electrodes, and removing the metal film layer in other parts.

In some other embodiments, the manufacturing process for depositing the metal film layer is selected from one or more of a high-temperature furnace, chemical vapor deposition, physical vapor deposition, or atomic layer deposition.

On the stack structure, a gate hole is formed by etching between the first electrode and the second electrode to ensure that the first electrode and the second electrode are exposed, and the active layer is formed between the first electrode and the second electrode in the gate hole. The gate structure is formed in the gate hole in which the active layer is formed, and the gate structure includes an outer gate insulating layer and a gate electrode wrapped in the gate insulating layer. A portion of the active layer, which is corresponding to the first electrode and the second electrode, is the channel region, and because the thickness of the first electrode and the thickness of the second electrode are related to the thickness of the supporting layer, the thickness of the channel region is also related to the thickness of the supporting layer.

In some other embodiments, the gate hole is formed before the first electrode and the second electrode are formed, or the gate hole is formed in the same step as the hole or groove formed when the first electrode and the second electrode are manufactured. After being manufactured, the gate hole is filled with a filling material. After the first electrode and the second electrode are formed, the filling material is removed to proceed to a subsequent step.

In some other embodiments, the manufacturing of the active layer includes: forming a continuous semiconductor material layer on a sidewall of the gate hole and filling the gate hole, where optionally, the gate hole is filled once the gate structure is manufactured or the gate hole is filled with a filling material; and removing the sacrificial layer in the stack structure to expose the semiconductor material layer, and etching away the semiconductor material layer at a position where the sacrificial layer is the least to form the active layer.

In some other embodiments, the gate structure is manufactured by first depositing the gate insulating layer, optionally one or more of an oxide, a nitride, or an oxynitride, and then manufacturing a gate, optionally one or more of a metal, an alloy, a conductive compound, or polysilicon, in the gate hole in which the gate insulating layer is deposited.

In some other embodiments, the plurality of first structural units are manufactured simultaneously. Grooves are manufactured in the stack structure, and the second electrodes and the bit lines are manufactured after the supporting layers are laterally etched through the grooves.

In some other embodiments, the bit line and the corresponding second electrodes are integrally formed.

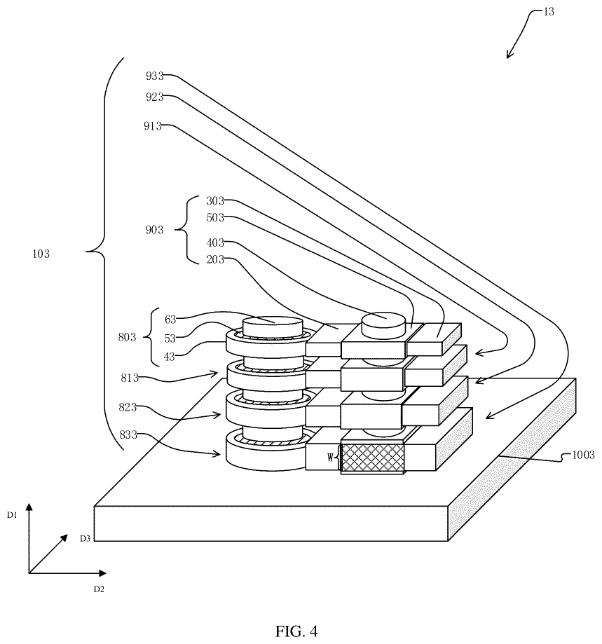

In some other embodiments of the present disclosure, a semiconductor device 13 shown in FIG. 4 is provided and includes: a first structural unit 103 disposed on a substrate 1003. The first structural unit includes: transistors (903, 913, 923, 933). A plurality of transistors (903, 913, 923, 933) are stacked along a first direction D1. The transistor (903) is used as an example and includes: a gate structure (403), an active layer (503) a first electrode (203), and a second electrode (303). The first electrode and the second electrode are disposed on two sides of the gate structure along a second direction D2. The active layer is connected to the first electrode and the second electrode; the active layer includes a channel region, and the channel region is located between the first electrode and the second electrode. Gate structures of the plurality of transistors (903, 913, 923, 933) are connected along the first direction D1. The first direction D1 intersects with a plane on which the substrate 1003 is located, and the second direction D2 intersects with the first direction D1. The plurality of transistors (903, 913, 923, 933) include at least a first transistor and a second transistor, where the width of the channel region of the transistor, for example, the first transistor 903, far away from the substrate along the first direction D1 is less than the width W of the channel region of the second transistor 933 close to the substrate. The first structural unit further includes capacitor structures (803, 813, 823, 833), where a plurality of capacitor structures (803, 813, 823, 833) are stacked along the first direction D1. The capacitor structure includes a first capacitor electrode 43, a second capacitor electrode 63, and a capacitor dielectric layer 53 disposed between the first capacitor electrode and the second capacitor electrode. The plurality of capacitor structures (803, 813, 823, 833) and the plurality of transistors (903, 913, 923, 933) are correspondingly disposed along the second direction D2, and the first capacitor electrode 43 of the capacitor structure is connected to the first electrode 203 of the corresponding transistor. Second capacitor electrodes of the plurality of capacitor structures are connected along the first direction.

In some other embodiments, the first capacitor electrode is disposed as a ring around the second capacitor electrode, and the width of the second capacitor electrode corresponding to the first transistor in the first direction is less than the width of the second capacitor electrode corresponding to the second transistor in the first direction. A specific manufacturing manner is as follows: First, a stack structure is manufactured on the substrate. The stack structure is made by depositing two different material layers alternately. The two material layers have a certain etching selectivity, which is used for selective etching in a subsequent manufacturing process to form a required structure. One material layer is a supporting layer and the other material layer is a sacrificial layer. Optionally, silicon layers and silicon germanium layers are deposited alternately to form a stack structure. Optionally, silicon nitride and silicon oxide are deposited alternately to form a stack structure. One or more of factors such as a deposition rate, a deposition time, a reaction temperature, or a reaction gas flow rate of each layer are adjusted to adjust the thickness of a deposited layer. The thickness of a supporting layer formed close to the substrate through deposition is greater than the thickness of a supporting layer far away from the substrate.

In some other embodiments, the thickness of the supporting layer decreases as the distance from the substrate increases.

In some other embodiments, as a whole, the thickness of the supporting layer decreases as the distance from the substrate increases, but thicknesses of adjacent supporting layers may be equal. For example, thicknesses of every few supporting layers are equal, and thicknesses of several supporting layers subsequently deposited are also equal but less than the thicknesses of several supporting layers previously deposited.

In some other embodiments, sacrificial layers have the same thickness.

In some other embodiments, similar to the supporting layer, the thickness of the sacrificial layer decreases as the distance from the substrate increases.

In some other embodiments, the sacrificial layer has an opposite trend to the supporting layer, that is, the thickness of the sacrificial layer gradually increases as the distance from the substrate increases.

In some other embodiments, the deposition method may be selected from one or more of a high-temperature furnace, chemical vapor deposition, physical vapor deposition, or atomic layer deposition.

Two holes or grooves are formed on the stack structure obtained above through etching, and the supporting layers are laterally etched through the holes or grooves to form lateral grooves. The first electrode and the second electrode are respectively formed in the lateral grooves of the two holes or grooves. Because the first electrode and the second electrode are formed in the lateral grooves and the width of the lateral grooves in the first direction is related to the thickness of the supporting layer, the thickness of the first electrode and the thickness of the second electrode are related to the thickness of the corresponding supporting layer.

In some other embodiments, the etching process for manufacturing holes or grooves is selected from dry etching or wet etching.

In some other embodiments, the etching process for lateral etching is selected from dry etching or wet etching.

In some other embodiments, the manufacturing method for the first electrode and the second electrode includes: first depositing a continuous metal film layer covering the surface of the stack structure, the surface of the hole or the groove, the substrate exposed by the hole or the groove, and the inside of the lateral grooves; and retaining the metal film layer in the lateral grooves by using an anisotropic etching method to form the first electrodes and the second electrodes, and removing the metal film layer in other parts.

In some other embodiments, the manufacturing process for depositing the metal film layer is selected from one or more of a high-temperature furnace, chemical vapor deposition, physical vapor deposition, or atomic layer deposition.

On the stack structure, a gate hole is formed by etching between the first electrode and the second electrode to ensure that the first electrode and the second electrode are exposed, and the active layer is formed between the first electrode and the second electrode in the gate hole. The gate structure is formed in the gate hole in which the active layer is formed, and the gate structure includes an outer gate insulating layer and a gate electrode wrapped in the gate insulating layer. A portion of the active layer, which is corresponding to the first electrode and the second electrode, is the channel region, and because the thickness of the first electrode and the thickness of the second electrode are related to the thickness of the supporting layer, the thickness of the channel region is also related to the thickness of the supporting layer.

In some other embodiments, the gate hole is formed before the first electrode and the second electrode are formed, or the gate hole is formed in the same step as the hole or groove formed when the first electrode and the second electrode are manufactured. After being manufactured, the gate hole is filled with a filling material. After the first electrode and the second electrode are formed, the filling material is removed to proceed to a subsequent step.

In some other embodiments, the manufacturing of the active layer includes: forming a continuous semiconductor material layer on a sidewall of the gate hole and filling the gate hole, where optionally, the gate hole is filled once the gate structure is manufactured or the gate hole is filled with a filling material; and removing the sacrificial layer in the stack structure to expose the semiconductor material layer, and etching away the semiconductor material layer at a position where the sacrificial layer is the least to form the active layer.

In some other embodiments, the gate structure is manufactured by first depositing the gate insulating layer, optionally one or more of an oxide, a nitride, or an oxynitride, and then manufacturing a gate, optionally one or more of a metal, an alloy, a conductive compound, or polysilicon, in the gate hole in which the gate insulating layer is deposited.

In some other embodiments, a hole is formed in the stack structure, the supporting layers are laterally etched in the hole to form lateral grooves, and then the first electrodes and the first capacitor electrodes are manufactured. Optionally, the first capacitor electrode is disposed in the lateral groove, and therefore, the width of the first capacitor electrode in the first direction is related to the thickness of the supporting layer.

In some other embodiments, the first electrode and the first capacitor electrode are integrally formed.

In some other embodiments, capacitor dielectric layers of the plurality of capacitor structures disposed along the first direction are formed in the same manufacturing process, and the capacitor dielectric layers of the plurality of capacitor structures may be continuous or independent of each other.

In some other embodiments, second capacitor electrodes of the plurality of capacitor structures disposed along the first direction are formed in the same manufacturing process.

In some other embodiments, the material of the active layer is an oxide semiconductor material.

In some other embodiments, the material of the active layer is indium gallium zinc metal oxide doped with tin.

In some other embodiments, the second electrode and/or the first electrode are selected from one or more of: metallic ruthenium, metallic molybdenum, ruthenium oxide, or molybdenum oxide.

In some other embodiments, the first capacitor electrode is selected from one or more of: metallic ruthenium, metallic molybdenum, ruthenium oxide, or molybdenum oxide.

In some other embodiments, the first capacitor electrode and the first electrode include metallic ruthenium.

In some other embodiments, the capacitor dielectric layer includes strontium titanium oxide.

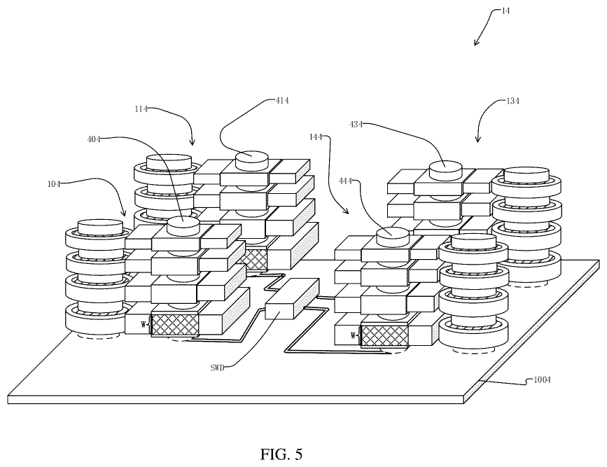

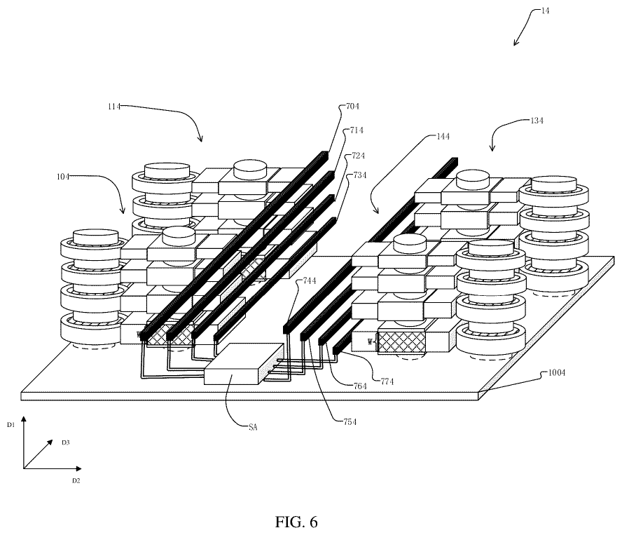

In some other embodiments of the present disclosure, a dynamic random access memory 14 shown in FIG. 5 and FIG. 6 is provided and includes the semiconductor device according to any one of the foregoing embodiments which optionally includes first structural units (104, 114, 134, 144) disposed on a substrate 1004. The dynamic random access memory 14 further includes: a sub-word line driver SWD connected to gate structures (404, 414, 434, 444) and a sense amplifier SA connected to second electrodes.

In some other embodiments, the sense amplifier SA is connected to the second electrodes by using bit lines (704, 714, 727, 734, 744, 754, 764, 774).

In some other embodiments, the sub-word line driver SWD and the sense amplifier SA are disposed in different regions of the substrate 1004.

In some other embodiments, the first structural units are manufactured on the same surface after the sub-word line driver SWD and the sense amplifier SA are formed on the substrate.

In some other embodiments, the first structural units are manufactured on an opposite surface after the sub-word line driver SWD and the sense amplifier SA are formed on the substrate, and the sub-word line driver SWD and the sense amplifier SA are linked to the first structural units through silicon vias (TSVs).

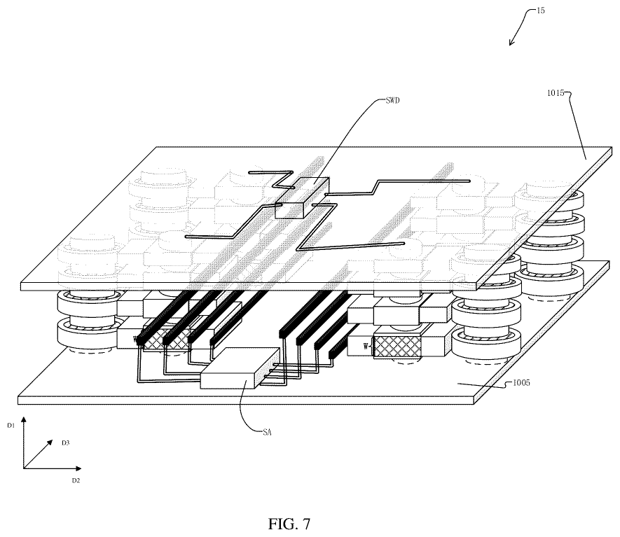

In some other embodiments of the present disclosure, a dynamic random access memory 15 shown in FIG. 7 is provided. A sub-word line driver SWD is disposed on a control substrate 1015, a sense amplifier SA is disposed on a substrate 1005, and the control substrate is bonded to the substrate.

In some other embodiments, the sub-word line driver SWD is disposed on the substrate 1005, the sense amplifier SA is disposed on the control substrate 1015, and the control substrate is bonded to the substrate.

In some other embodiments, the sub-word line driver SWD and the sense amplifier SA are both disposed on the control substrate 1015, which is bonded to the substrate 1005 on which the first structural units are disposed, the sub-word line driver SWD is connected to gate structures of the first structural units through wiring, and the sense amplifier SA is connected to second electrodes through wiring.

In some other embodiments, the control substrate and the substrate are bonded by hybrid bonding.

Beneficial effects of the embodiments of the present disclosure are as follows:
The thicknesses of the supporting layers in the stack structure are set, so that during the manufacturing of transistors disposed in a stacked manner, the stacked transistors with a structure that the width of the lower-layer channel is large and the width of the upper-layer channel is small is obtained, thus compensating for the impact, on the performance of the transistors, of a tapered cross section formed when the gate hole is etched, thereby obtaining a semiconductor device with better uniformity.

Because the transistor is disposed at a corresponding position of the supporting layer, the impact of the thickness change of the supporting layer on the process may be compensated for when the sacrificial layer has an opposite trend compared with the supporting layer, and the channel width of the transistor is not affected.

For the capacitor structure disposed in the hole, the first capacitor electrode is of a ring shape and is also affected by the tapered cross section of the hole, and the diameter of the first capacitor electrode of the upper-layer capacitor structure is greater than the diameter of the first capacitor electrode of the lower-layer capacitor structure. Therefore, allowing the width of the first capacitor electrode in the first direction to decrease as the distance from the substrate increases can compensate for the impact of the diameter of the first capacitor electrode increasing as the distance from the substrate increases, thereby enabling the area of the upper-layer first capacitor electrode to be close to the area of the lower-layer first capacitor electrode and finally making the capacitance of the upper and lower capacitor structures close. In this case, a semiconductor device with a higher uniformity is obtained.

For the active layer, an oxide semiconductor material is selected for easier manufacturing.

When indium gallium zinc metal oxide doped with tin is selected for the active layer, the semiconductor has better performance.

One or more of metallic ruthenium, metallic molybdenum, ruthenium oxide, or molybdenum oxide are selected for the first electrode and the second electrode. When an oxide semiconductor material is selected for the active layer, the ruthenium oxide or the molybdenum oxide, since they are oxides, will not be affected by the oxide semiconductor material, and the metallic ruthenium and the metallic molybdenum are also conductors when affected by oxygen in the oxide semiconductor material to form oxides and therefore, unlike other metals, the metallic ruthenium and the metallic molybdenum will not be affected by oxygen in the oxide semiconductor material to form oxides and thereby cause resistance to increase.

When the metallic ruthenium is selected for the first capacitor electrode and the strontium titanium oxide is selected for the capacitor dielectric layer, because the lattice constant of the metal ruthenium is close to that of the strontium titanium oxide, the metal ruthenium may be used as a seed layer to induce the strontium titanium oxide to deposit, which is beneficial to the process and the device performance.

The sub-word line driver SWD and the sense amplifier SA are both disposed on the control substrate and then bonded to the substrate on which the first structural units are disposed. The design allows for easier manufacturing. The two different processes for the sub-word line driver SWD, the sense amplifier SA, and the first structural units do not affect each other, and thus a semiconductor device with better performance can be obtained.

By hybrid bonding, bonding pads can be arranged more densely to encapsulate the control substrate and the substrate, which enables to obtain a semiconductor device with better performance.

Although the present disclosure has been described in detail with reference to the above embodiments, those of ordinary skill in the art will appreciate that the technical solutions described in the foregoing embodiments may still be modified, or some of the technical features may be equivalently replaced; the modifications or replacements do not cause the essence of the corresponding technical solutions to depart from the spirit and scope of the technical solutions of the embodiments of the present disclosure.

What is claimed is:

1. A semiconductor device, comprising:
a substrate; and
a first structural unit disposed on the substrate, the first structural unit comprising:
a plurality of transistors, the plurality of transistors being stacked along a first direction, wherein
each of the plurality of transistors comprises: a gate structure, an active layer, a first electrode, and a second electrode, the first electrode and the second electrode being respectively disposed on two sides of the gate structure along a second direction, the active layer being connected to the first electrode and the second electrode, the active layer comprising a channel region, and the channel region being located between the first electrode and the second electrode;
the gate structures of the plurality of transistors are connected along the first direction;
the first direction intersects with a plane on which the substrate is located, and the second direction intersects with the first direction;
the plurality of transistors comprise at least a first transistor and a second transistor, wherein a width of a channel region of the first transistor far away from the substrate along the first direction is less than a width of a channel region of the second transistor close to the substrate.

2. The semiconductor device according to claim 1, wherein for widths of channel regions of the plurality of transistors, the farther away from the substrate along the first direction, the smaller a width of a channel region.

3. The semiconductor device according to claim 1, comprising a plurality of first structural units stacked along the first direction, the gate structures of the plurality of first structural units being connected along the first direction.

4. The semiconductor device according to claim 1, comprising a plurality of first structural units disposed along a third direction, wherein the third direction intersects with the second direction;
the second electrodes of the transistors disposed at a same layer of the plurality of first structural units are connected to a same bit line, and the bit line is disposed along a third direction.

5. The semiconductor device according to claim 1, wherein the first structural unit further comprises:
a plurality of capacitor structures, the plurality of capacitor structures being stacked along the first direction, wherein
each of the plurality of capacitor structures comprises a first capacitor electrode, a second capacitor electrode, and a capacitor dielectric layer disposed between the first capacitor electrode and the second capacitor electrode;
the plurality of capacitor structures and the plurality of transistors are correspondingly disposed along the second direction, and the first capacitor electrode of the capacitor structure is connected to the first electrode of a corresponding transistor;
the second capacitor electrodes of the plurality of capacitor structures are connected along the first direction.

6. The semiconductor device according to claim 5, wherein the first capacitor electrode is disposed as a ring around the second capacitor electrode, and a width of the second capacitor electrode corresponding to the first transistor in the first direction is less than a width of the second capacitor electrode corresponding to the second transistor in the first direction.

7. The semiconductor device according to claim 1, wherein a material of the active layer is indium gallium zinc metal oxide doped with tin.

8. The semiconductor device according to claim 1, wherein the second electrode and/or the first electrode are selected from one or more of: metallic ruthenium, metallic molybdenum, ruthenium oxide, or molybdenum oxide.

9. The semiconductor device according to claim 5, wherein the first capacitor electrode is selected from one or more of: metallic ruthenium, metallic molybdenum, ruthenium oxide, or molybdenum oxide.

10. The semiconductor device according to claim 5, wherein the first capacitor electrode and the first electrode are integrally formed.

11. The semiconductor device according to claim 10, wherein the first capacitor electrode and the first electrode comprise metallic ruthenium.

12. The semiconductor device according to claim 11, wherein the capacitor dielectric layer comprises strontium titanium oxide.

13. A dynamic random access memory, comprising: the semiconductor device according to claim 1;
a sub-word line driver connected to the gate structures; and
a sense amplifier connected to the second electrodes.

14. The dynamic random access memory according to claim 13, wherein the sub-word line driver and/or the sense amplifier are disposed on the substrate.

15. The dynamic random access memory according to claim 13, wherein the sub-word line driver and/or the sense amplifier are disposed on a control substrate, the control substrate being bonded to the substrate.

16. A method for manufacturing a semiconductor device, comprising:
providing a substrate;
forming a stack structure on the substrate, by alternately forming first layers and second layers, wherein a thickness of one of the first layers far from the substrate is less than a thickness of another one of the first layers close to the substrate;
forming a first structural unit in the stack structure, the first structural unit comprising:
a plurality of transistors, the plurality of transistors formed in the first layers, wherein
each of the plurality of transistors comprises: a gate structure, an active layer, a first electrode, and a second electrode, the first electrode and the second electrode being respectively disposed on two sides of the gate structure along a second direction, the active layer being connected to the first electrode and the second electrode, the active layer comprising a channel region, and the channel region being located between the first electrode and the second electrode;
the gate structures of the plurality of transistors are connected along a first direction;
the first direction intersects with a plane on which the substrate is located, and the second direction intersects with the first direction.

17. The method according to claim 16, wherein for thicknesses of the first layers, the farther away from the substrate, the smaller a thickness of the first layers.
